(19) United States
(12) Patent Application Publication
(10) Pub. No.: US 2006/0002305 A1
(43) Pub. Date: Jan. 5, 2006

(54) Generation of stressed flow of packets

(75) Inventor: Josef Yossi Ginzburg, Binyamina (IL)

Correspondence Address: INTERNATIONAL BUSINESS MACHINES CORPORATION;DEPT. 18G, BLDG. 300-482, 2070 ROUTE 52, HOPEWELL JUNCTION, NY, 12533, US

(73) Assignee: INTERNATIONAL BUSINESS MACHINES CORPORATION, ARMONK, NY (US)

(21) Appl. No.: 10/882,065

(22) Filed: Jun. 30, 2004

(51) Int. Cl. G06F 11/00; H04J 3/14; H04J 1/16; G01R 31/08; H04L 12/66; G08C 15/00; H04L 12/26; H04L 1/00

(52) U.S. Cl. 370/241

(57) ABSTRACT

A method and system for generating streams of packets of data, including generating a flow of packets of data to a switch assembly, the switch assembly including a traffic generating loop including at least two ports in loopback mode, and multicasting packets of data from a first port of the traffic generating loop to a second port of the traffic generating loop and to an output port of the switch assembly adapted to output the packets, and looping packets back from the second port to the first port of the traffic generating loop.

### FIELD OF THE INVENTION

The present invention relates generally to the generation of stressed flow of packets in a switched network.

### BACKGROUND OF THE INVENTION

Point-to-point, switched I/O (input/output) architectures are well known in the art, such as InfiniBand. By means of switches, multiple points can be interconnected to create a so-called fabric. Increasing the number of switches increases the bandwidth of the fabric. By adding multiple paths between devices, switches also provide a greater level of redundancy.

In a typical InfiniBand fabric, a Host Channel Adapter (HCA) is an interface that resides within a server and communicates directly with the server's memory and processor. The HCA guarantees delivery of data, performs advanced memory access and can recover from transmission errors. A Target Channel Adapter (TCA) can enable I/O devices, such as disk or tape storage, to be located within the network independent of a host computer. The TCA typically includes an I/O controller that is specific to its particular device's protocol (i.e., SCSI, Fiber Channel or Ethernet). The switch allows many HCAs and TCAs to connect to it and handles network traffic.

Generation of stressed traffic is an accepted and common method for checking the behavior and reliability of components of such switched I/O systems during the initial introduction and test phase. Traffic generators are commercially available that are designed to generate test traffic in a controllable way (e.g., the Agilent Technologies E2953A Traffic Generator for InfiniBand 1×). The traffic generator may generate sequences of arbitrary packets and respond to incoming packets in real-time.

However, in the early stages of development, traffic generators may have limited performance and high cost.

For example, prior art traffic generators operate by connection to a host computer, such as via the channel adapter. There are drawbacks to this approach. First, the transmission rate is limited by the software that is running on the host computer and by the capability of the channel adapter. For example, in a functional validation test, stressed traffic may be difficult to generate if the generator has a limited rate at which it can inject packets, compounded by the limitations of the HCA and TCA. Second, traffic diversity is limited, that is, changing the type or contents of the packets is limited by the software and host operation. Third, traffic generators are usually quite costly devices.

### SUMMARY OF THE INVENTION

The present invention seeks to provide an improved system and method for the generation of stressed flow of packets, as is described more in detail hereinbelow.

In accordance with a non-limiting embodiment of the present invention, high rate traffic may be generated by utilizing an off-the-shelf switch, programmed to work in loopback mode.

The present invention has several advantages. First, the only limit to the transmission rate is the switch's own throughput. It is not limited by any interface with the host computer. Second, the system can support and use any type of packet with any type of contents. The system can support as many different packets as its buffers allow. Third, an off-the-shelf switch may be significantly less expensive than custom-made traffic generators.

### BRIEF DESCRIPTION OF THE DRAWINGS

The present invention will be understood and appreciated more fully from the following detailed description taken in conjunction with the appended drawings in which:

FIG. 1 is a simplified block diagram of a switched I/O system, in accordance with an embodiment of the present invention;

FIG. 2 is a simplified block diagram that illustrates using the system of FIG. 1 to perform different stress tests, in accordance with an embodiment of the present invention; and

FIG. 3 is a simplified flow chart of stressing a port with the system of FIG. 1 in accordance with a pass/fail criterion, in accordance with an embodiment of the present invention; and

FIG. 4 is a simplified flow chart of performing a link stress test with the system of FIG. 1, in accordance with an embodiment of the present invention.

### DETAILED DESCRIPTION OF EMBODIMENTS

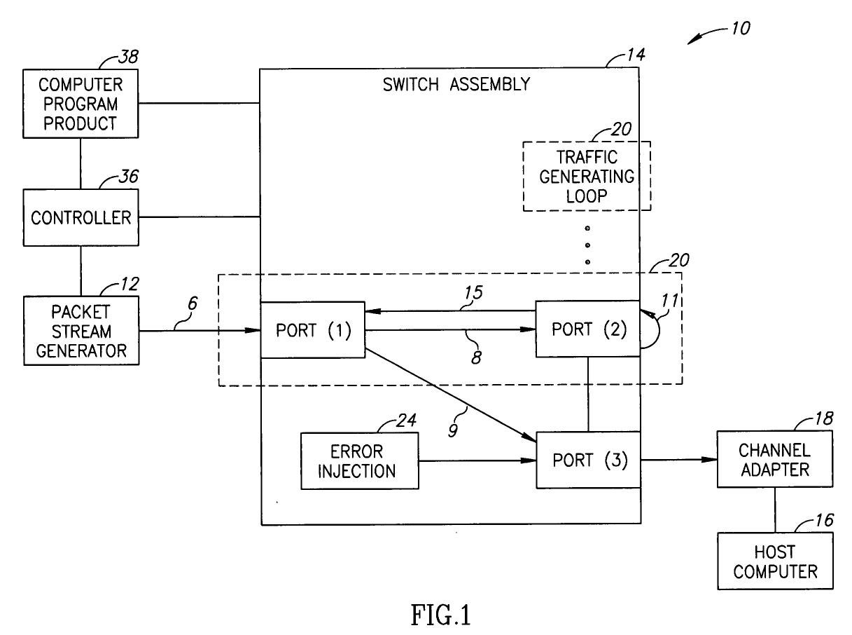

Reference is now made to FIG. 1, which illustrates a switched I/O system 10, in accordance with an embodiment of the present invention.

The system 10 may include a packet stream generator 12 of any size and capability (e.g., 1×, 4×, etc.), commercially available from a variety of manufacturers (e.g., Agilent Technologies). The packet stream generator 12 may be, for example, an HCA, TCA or switch. The packet stream generator 12 may generate a flow of packets that is switched and controlled by a switch assembly 14 for output to a host computer 16, such as via a channel adapter 18. As is described more fully hereinbelow, switch assembly 14 may comprise any number of switches, which may be typically used in point-to-point, switched I/O fabric architectures, such as but not limited to, InfiniBand. As is well known in the art, typical features of such switches include, but are not limited to, loopback mode and error injection. Such switches are commercially available (“off-the-shelf”) from a variety of manufacturers (e.g., Cisco Systems or Patton Electronics).

For the sake of simplicity, only one switch is shown in the switch assembly 14 of FIG. 1, but it is understood that the switch assembly 14 may comprise any number of switches. In the following description, the switch assembly 14 will be referred to simply as switch 14.

In the non-limiting example shown in FIG. 1, the packet stream generator 12 generates traffic on port(1) of switch 14 (arrow 6). Switch 14 may have two ports in loopback mode, port(1) and port(2). The loop between port(1) and port(2) is referred herein as a “traffic generating loop 20”. Port(1) may multicast packets to port(2) (arrow 8) and port(3) (arrow 9). Port(2) may loop (arrow 11) the packets back to port(1) (arrow 15). In this manner, port(3) generates a constant flow of packets out to the channel adapter 18 and the host computer 16. (either the channel adapter 18 or the host computer 16 or both may be considered as a “unit or device under test”.)

The system 10 can efficiently control the stream of packets, for example, by selecting which packets shall be injected into the traffic generating loop 20. For example, multicast packets may be injected into the traffic generating loop 20 (arrow 6), whereas single packets can be injected to the constant stream by forwarding them via an input port to an output port—for example, to port(1) (arrow 6) and then to port(3) (arrow 9). Errors may be injected into the traffic generating loop 20 by using an error injection feature 24 of the switch 14, e.g., to output port(3).

Each switch 14 may have a multiplicity of ports, and accordingly may have more than one traffic generating loop 20. Moreover, one individual traffic generating loop 20 may generate traffic to several output ports, thus generating several traffic sources (this feature being implemented further hereinbelow for stressing an output port, as explained further on). Furthermore, the invention is not limited to using just two ports of the switch 14 for the traffic generating loop 20. Rather, any plurality of ports (two or more) of the switch 14 may participate in the traffic generating loop 20, thereby increasing the total buffer size and the total number of packet types generated.

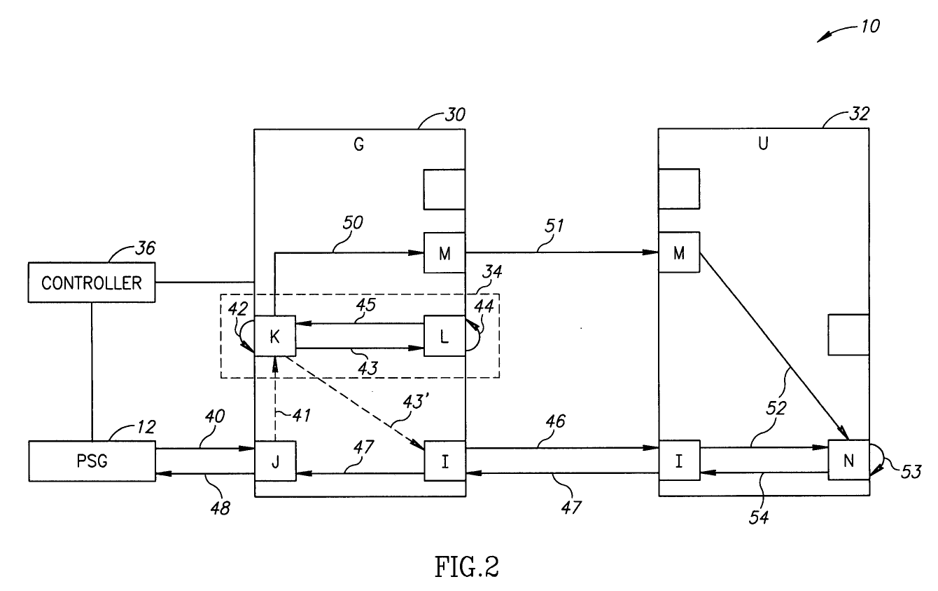

Reference is now made to FIG. 2, which illustrates using the system 10 to perform different stress tests, in accordance with an embodiment of the present invention. As mentioned above, the packet stream generator 12 may generate multicast packets, which run in loopback mode. The test environment may include a switch 30 that switches the traffic generated by the packet stream generator 12, and another switch 32, which is part of a unit under test. The switches 30 and 32 may be embodied in switch boards, wherein the board with switch 30 generates traffic and the one with switch 32 is under test.

The following nomenclature will be used for convenience of explanation. The i-th port of switch 30 (used in generating traffic) will be referred to as port [G,i] (“G” for generation). The i-th port of switch 32 (used in the unit under test) will be referred to as port [U,i] (“U” for under test).

Input port load and stress generation is now explained, wherein it is desired to stress (that is, load) an input port [U,i].

Switch 30 may have a traffic generating loop 34 comprising two ports in loopback mode, port[G,k] and port[G,l]. A controller 36 may be provided for controlling operation of the packet stream generator 12. The controller 36 may comprise, without limitation, forward debugging capability and a multicast forwarding database, for example.

It is noted that the operation of controller 36 or any other part of system 10 may be carried out by a computer program product 38, such as but not limited to, Network Interface Card, hard disk, optical disk, memory device and the like, which may include instructions for carrying out the methods described hereinabove.

The packet stream generator 12, as controlled by controller 36, may generate multicast packets and inject them through port[Gj] (arrow 40). The incoming packets may be forwarded from port[Gj] to port[G,k] (arrow 41), looped back from output port[G,k] to input port[G,k] (arrow 42), multicast from input port[G,k] to port[G,i] and port[G,l] (arrows 43 and 43′), and then looped back to port[G,l] (arrow 44) and forwarded to port[G,k] (arrow 45). Accordingly, the incoming packet continuously runs in a loop between port[G,k] and port[G,l]. Each time the incoming packet enters input port[G,k] it generates a noise packet (also called a traffic packet) towards port[G,i] (arrow 43′). To increase the number of traffic packets generated, more packets may be entered into the traffic generating loop 34. The packets do not have to be identical, but rather may have different features and/or parameters (such as length or virtual lane in InfiniBand). In this manner, a constant stream of traffic may be generated from output port[G,i] to input port [U,j] (arrow 46). Switch 32 may eventually service the packets or discard them, in order to prevent the system from reaching deadlock.

To finish the test, the traffic generating loop 34 may be “opened” or “broken”, wherein the remaining packets in the system may be forwarded to port[U,j] (arrows 47) and cleared out of the system (arrow 48).

The present invention may be used to stress an output port [U,n]. This may be accomplished by multicasting the packet to more than two output ports of switch 30 (for example, in addition to port [G,i], another port[G,m], as indicated by arrow 50), which are connected to the input ports of switch 32 (for example, in addition to port [U,i], another port[U,m], as indicated by arrow 51), and then forwarding all of them to a single output port [U,n] (arrows 52).

The present invention may be used to load any kind of output port. For example, in InfiniBand, a management port may be stressed. This may be accomplished just as described previously for stressing the output port [U,n], except the destination port[U,n] is set to zero, and the packets are discarded or sent back to the packet stream generator 12, e.g., by the OMA (object management architecture), as indicated by arrows 53, 54,47 and 48.

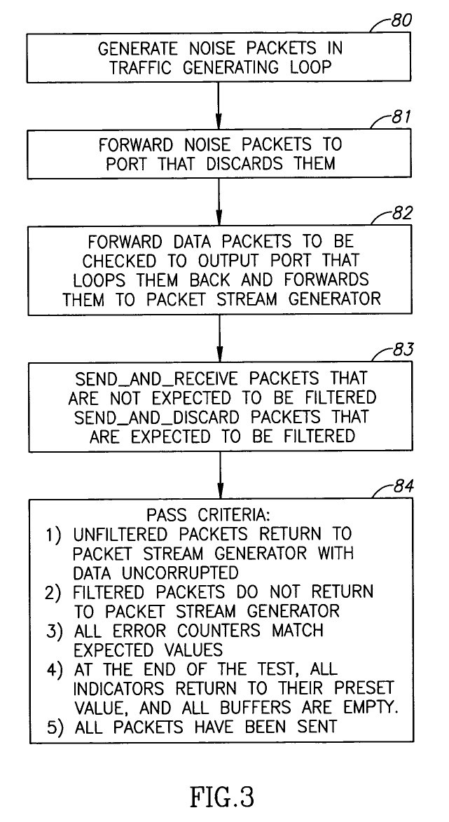

Reference is now made to FIG. 3, which illustrates (in flow chart form) using the system 10 to stress a port, in accordance with a pass/fail criterion, in accordance with an embodiment of the present invention.

Noise packets may be generated in the traffic generating loop 34, as described previously with reference to FIG. 2 (step 80). The noise packets may be forwarded to a port that discards them (step 81). Data packets that are to be checked may be forwarded to an output port that loops them back and forwards them to the packet stream generator 12 (step 82). The controller 36 may have send_and_receive and send_and_discard functionality. Send_and_receive may be used for packets that are not expected to be filtered. Send_and_discard may be used for packets that are expected to be filtered (step 83).

The pass criteria (step 84) may be as follows (otherwise the data are considered to fail the test):

1) Packets that are not to be filtered return to the generator 12 with the data uncorrupted.

2) Packets that are to be filtered do not return to the generator 12.

3) All Error counters match expected values.

4) At the end of the test, all indicators have returned to their initial value.

5) All packets have been sent (meaning that the test did not get stuck, and switch did not hang)

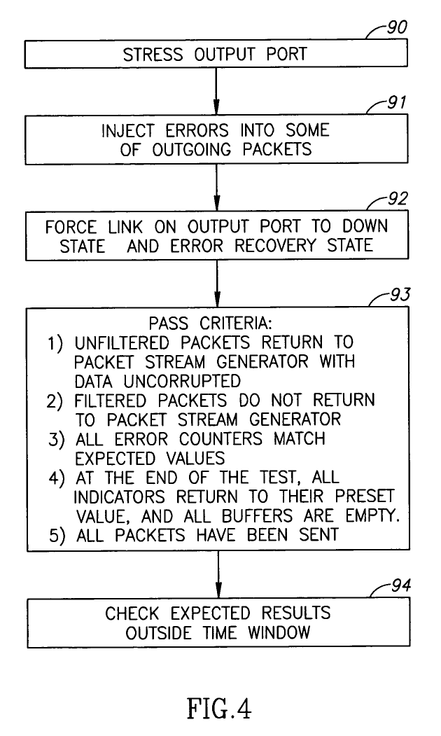

Reference is now made to FIG. 4, which illustrates (in flow chart form) using the system 10 to perform a link stress test, in accordance with an embodiment of the present invention, wherein the link is stressed before and after the link fails.

To perform the link stress test, the procedure used to stress the output port [U,n] may be followed as described hereinabove (step 90). In addition, errors may be injected into some of the outgoing packets on port[Gj] (step 91). The link on output port [U,n] may be forced to the DOWN state and error recovery state (step 92). The pass/fail criteria used for the port stress described above in step 84 in the embodiment of FIG. 3 may also be used here (step 93), except that expected results may be checked outside some time window before and after the link was down or recovering (step 94).

The description of the present invention has been presented for purposes of illustration and description, and is not intended to be exhaustive or limited to the invention in the form disclosed. Many modifications and variations will be apparent to those of ordinary skill in the art. The embodiment was chosen and described in order to best explain the principles of the invention, the practical application, and to enable others of ordinary skill in the art to understand the invention for various embodiments with various modifications as are suited to the particular use contemplated.

What is claimed is:

1. A method for generating streams of packets of data, the method comprising:
receiving a flow of packets of data to a switch assembly, said switch assembly comprising a traffic generating loop comprising at least two ports in loopback mode; and
multicasting packets of data from a first port of the traffic generating loop to a second port of the traffic generating loop and to an output port of the switch assembly adapted to output the packets, and looping packets back from the second port to the first port of the traffic generating loop.

2. The method according to claim 1, further comprising injecting errors into said traffic generating loop.

3. The method according to claim 1, wherein said traffic generating loop multicasts packets to more than one output port.

4. The method according to claim 1, wherein the output port of the switch assembly outputs the packets to a host computer.

5. The method according to claim 1, wherein an incoming packet to the switch assembly continuously runs in a loop between ports of the traffic generating loop, and each time the incoming packet enters an input port of the switch assembly the packet generates a noise packet towards the output port of the switch assembly.

6. The method according to claim 5, wherein the output port of the switch assembly outputs the packets to an input port of a unit under test.

7. The method according to claim 5, further comprising multicasting packets to more than two output ports of said switch assembly, outputting the packets to input ports of a unit under test, and forwarding the packets to an output port of the unit under test.

8. The method according to claim 7, further comprising setting said output port of the unit under test to zero and discarding the packets.

9. The method according to claim 7, further comprising setting said output port of the unit under test to zero and sending the packets to a packet stream generator.

10. The method according to claim 8, further comprising checking data packets generated by a packet stream generator to the switch assembly by forwarding the data packets to an output port of the switch assembly that loops them back and forwards them to the packet stream generator, wherein pass criteria of the data packets comprise:
1) packets that are not to be filtered return to the packet stream generator with the data uncorrupted; and
2) packets that are to be filtered do not return to the packet stream generator.

11. A system for generating streams of packets of data, the system comprising:
a switch assembly; and
a packet stream generator adapted to generate a flow of packets of data to said switch assembly, said switch assembly comprising a traffic generating loop comprising at least two ports in loopback mode, wherein a first port of the traffic generating loop is adapted to multicast packets to a second port of the traffic generating loop and to an output port of the switch assembly adapted to output the packets to a host computer, and wherein the second port of the traffic generating loop is adapted to loop packets back to the first port of the traffic generating loop.

12. The system according to claim 11, wherein said output port outputs the packets to a host computer via a channel adapter.

13. The system according to claim 11, wherein said switch assembly comprises an error injection feature for injecting errors into said traffic generating loop.

14. The system according to claim 11, wherein said switch assembly comprises more than one traffic generating loop.

15. The system according to claim 11, wherein said traffic generating loop is adapted to multicast packets to more than one output port.

16. The system according to claim 11, further comprising a controller adapted to control operation of the packet stream generator.

17. The system according to claim 11, further comprising a controller adapted to control operation of the packet stream generator.

18. The system according to claim 11, wherein said packet stream generator adapted to generate packets of InfiniBand traffic.

19. A computer program product for generating streams of packets of data, the computer program product comprising:
instructions for generating a flow of packets of data to a switch assembly, said switch assembly comprising a traffic generating loop comprising at least two ports in loopback mode; and
instructions for multicasting packets of data from a first port of the traffic generating loop to a second port of the traffic generating loop and to an output port of the switch assembly adapted to output the packets, and looping packets back from the second port to the first port of the traffic generating loop.

20. The computer program product according to claim 18, further comprising instructions for injecting errors into said traffic generating loop.

21. The computer program product according to claim 18, further comprising instructions for said traffic generating loop to multicast packets to more than one output port.
